(19) United States
(12) Patent Application Publication
(10) Pub. No.: US 2019/0086448 A1
(43) Pub. Date: Mar. 21, 2019

(54) Brush Wheel Assemblies with Active Guide Discs for In-Line Inspection Tool

(71) Applicant: Baker Hughes, a GE company, LLC, Houston, TX (US)

(72) Inventors: Mikhail Anisimov, Calgary (CA); Gerald Alingig, Calgary (CA); Ihor Rybak, Etobicoke (CA)

(73) Assignee: Baker Hughes, a GE company, LLC, Houston, TX (US)

(21) Appl. No.: 15/708,777

(22) Filed: Sep. 19, 2017

(51) Int. Cl. G01R 19/00; G01N 17/04

(52) U.S. Cl. CPC G01R 19/0046; F16L 2101/30; G01N 17/04

(57) ABSTRACT

A device for measuring a voltage differential communicated through a portion of a pipe or pipeline includes electrical contact assemblies which feature brush wheel assemblies. The brush wheel assemblies incorporate at least one brush wheel and at least one active guide disc which helps to absorb vibration, maintain even preload at the contact face of the rotating brush and ensure improved electrical contact between the brush wheel and the pipe.

### BACKGROUND OF THE INVENTION

### 1. Field of the Invention

The invention relates generally to the design of in-line pipeline inspection tools.

### 2. Description of the Related Art

Pipelines often carry liquids and gases under high pressure. The carried liquids and gases may contain solids or corrosives which can damage the pipeline. Thus, it has become increasingly important to monitor the interior surfaces of pipelines to be able to correct physical damage, corrosion, rust, contamination or other problems.

In-line inspection tools are used to examine the interior surfaces of pipelines to ensure their integrity. One variety of in-line inspection tool is commonly referred to as a pig. Pigs travel within the pipeline under pressure. Many contemporary in-line inspection tools contain on-board sensors and data recording equipment. As a result, they are often referred to as “smart” pigs.

One type of in-line inspection tool is a tool that measures the voltage differential along the inner surface of the pipe. The tool provides a measure of the effectiveness of applied corrosion protection for a pipeline and the need for corrective actions to be taken to prevent problematic corrosion. The tool measures a voltage drop across a short distance of the pipeline. To do this, the tool provides two distinct electrical contact points with the pipeline wall which are separated by a known distance. The measured voltage drop is then used to calculate the DC current and current density.

Many current designs for tools that measure voltage differential incorporate rotating bare steel brushes to form the electrical contact points. The inventor has determined, however, that current designs are vulnerable during operation to vibration which can lead to variability in contact pressure and increased undesirable friction and temperature. In dry gas environments, these effects become even worse as compared to liquid pipelines. Increased dynamics at the contact surfaces of the rotating steel brushes introduce background noise into the measured electrical signal, even where there is perfect electrical contact with the surface of the pipe. Further, the rotating steel brushes are vulnerable to deformation when they are located at the low side of the surrounding pipeline with the weight of the tool being applied to them. The rotating steel brush's bristles can be bent, which also introduces background noise into the measured signal.

### SUMMARY OF THE INVENTION

The invention provides a pipe inspection tool having an improved design for maintaining contact with a pipe wall and yield improved data relating to the condition of the pipeline. An exemplary tool is described which includes a central shaft assembly which carries several flexible curved cups which permit the tool to be carried through a pipeline along with fluid within the pipeline. First and second electrical contact assemblies are carried by the central shaft assembly and are spaced apart from one another by a set distance. Each of the electrical contact assemblies preferably includes a number of support arms which extend radially outwardly from the central shaft assembly in multiple radial directions so as to support the shaft assembly regardless of the angular orientation of the tool within the pipeline.

Each of the support arms carries a brush wheel assembly which is used to maintain electrical contact between the electrical contact assemblies and the interior surface of the pipeline. A first described brush wheel assembly includes a brush wheel having conductive bristles which is mounted for rotation upon an axle. The axle also carries at least one active guide disc. In the described embodiment, there is an active guide disc mounted on the axle on each axial side of the brush wheel. Preferably, the radius of the active guide discs is essentially the same as the radius provided by the bristles of the brush wheel so that the active guide discs will contact and ride upon the pipeline surface at the same time as the bristles. The use of active brush wheels limits the ability of vibration to affect electrical contact between the brush wheel and the surrounding pipe. In addition, the active brush wheels help to prevent rotating brush wheel slippage during operation.

A second brush wheel assembly is described wherein the brush wheel and the active guide discs are carried by independent suspensions. In the described embodiment, a first axle carries the brush wheel while a second, independent axle carries the active guide discs. Furthermore, the suspensions for both the active guide discs and the rotating brush wheel can be mounted on the two separate suspensions in the form of a swing arm linkage attached in series.

Also in described embodiments, the active guide disc includes an outer contact disc and an axle dampener which is disposed radially between the contact disc and its axle. The axle dampener absorbs physical vibration forces imparted to the contact disc. Axle dampeners are described which are formed of resilient, flexible material, such as polyurethane. Other axle dampeners are described which incorporate leaf springs which absorb energy resulting from relative motion between inner and outer frames. Additionally, axle dampeners are described in which deformable spokes interconnect inner and outer frames. The spokes elastically deform by bending in response to external forces imparted to the outer frame. The spokes have shape memory which permits them to return to their original shape after removal of the external force.

The tool also includes a measurement device for measuring the amount of current drop along the pipeline between the electrical contact assemblies.

Active guide discs help to prevent the bristles of the brush wheel from experiencing variable load under the weight of the tool when the brush wheels are on the low side, or lower half, of the pipe. The rigid contact disc portions of the active guide discs will prevent bending of the bristles. Resilient axle dampeners within the active guide discs will also absorb vibration and permit the axle bearing the brush wheel to be biased toward the surface of a surrounding pipe to positively ensure bristle-wall contact.

The guide discs and brush wheels of the brush wheel assembly may be biased, or preloaded, radially outwardly in order to ensure bristle-wall contact, even when the brush wheel assembly is located on the high side, or upper half, of the pipe. The bias or preload can be accomplished by means of springs, hydraulics or the like applied to the support arms for the brush wheel assemblies. Where separate axles are used, it is currently preferred that the active guide discs be provided with a higher preload or bias than that applied to the brush wheel itself. A differential preload or bias can be accomplished using separate axle support brackets with varying degrees of stiffness.

### BRIEF DESCRIPTION OF THE DRAWINGS

For a thorough understanding of the present invention, reference is made to the following detailed description of the preferred embodiments, taken in conjunction with the accompanying drawings, wherein like reference numerals designate like or similar elements throughout the several figures of the drawings and wherein:

FIG. 1 is an isometric view of an exemplary in-line pipeline inspection tool

FIG. 2 is a side, cross-sectional view of an exemplary brush wheel assembly constructed in accordance with the present invention.

FIG. 3 is a side view of an exemplary axle damper formed of a flexible, deformable material in accordance with the present invention.

FIG. 4 is a side view of an exemplary axle damper which incorporates leaf spring spokes.

FIG. 5 is a side view of an exemplary axle damper which incorporates deformable spokes.

FIG. 6 is a side, cross-sectional view of an alternative exemplary brush wheel assembly constructed in accordance with the present invention.

FIG. 7 is a side view of a further exemplary active guide disc constructed in accordance with the present invention.

FIG. 8 is an exploded view of the active guide disc shown in FIG. 7.

FIG. 9 is a cross-sectional view depicting an exemplary in-line pipeline inspection tool, in accordance with the present invention, disposed within a pipe for measurement of conductivity of a portion or the surrounding pipe.

FIG. 10 is a schematic axial cross-section taken along lines 8-8 in FIG. 7.

### DETAILED DESCRIPTION OF THE PREFERRED EMBODIMENTS

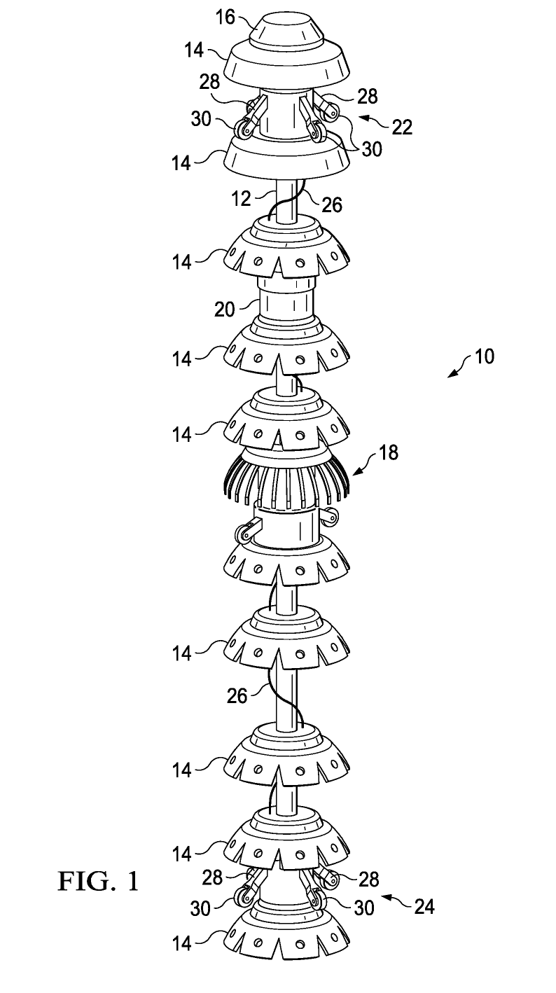

FIG. 1 depicts an exemplary in-line pipeline inspection tool or device 10. The tool 10 includes a central shaft assembly 12 which carries a plurality of shaped cups 14 for capturing fluid. The shaft assembly 12 may be of unitary construction but is more typically made up of a series of interconnected subs and shaft sections which are secured to one another in sequential fashion. The cups 14 are typically formed of polyurethane or another flexible material. During operation, the cups 14 typically contact the inner surface of the pipeline and function to centralize the shaft assembly 12 within the pipeline. In addition, the cups 14 are curved to capture pressurized fluid which helps move the tool 10 along the pipeline. A generally conical nose cone 16 is located at the axial end of the central shaft assembly 12 and is the portion of the tool 10 which is inserted first into a pipeline. The tool 10 carries a caliper section 18 which is used to detect deformation or alignment problems in a surrounding pipeline.

The tool 10 includes electrical voltage measurement device 20, such as a voltmeter, to measure the amount of voltage drop across a portion of the pipeline. In particular, the voltage measurement device 20 measures the amount of voltage drop between electrical contact assemblies 22, 24.

The tool 10 carries first and second electrical contact assemblies, generally shown at 22, 24, respectively. Each electrical contact assembly 22, 24 is designed to contact the interior surface of a pipeline through which the tool 10 is moving and ensure communication of the voltage differential measured by the voltage measurement device 20 over the pipeline surface. Electrical wiring 26 interconnects the electrical voltage measurement device 20 with the electrical contact assemblies 22, 24. Because the electrical contact assemblies 22, 24 are located a known, set distance from one another, a drop in voltage between the two contact assemblies through the pipeline surface can be measured. The measured voltage drop is then used to calculate the DC current and current density.

Each electrical contact assembly 22, 24 includes a plurality of electrically conductive support arms 28 which extend radially outwardly from the central shaft assembly 12. Multiple support arms 28, which extend radially outwardly from the shaft assembly 12 in multiple radial directions, are preferred to support the shaft assembly 12 regardless of the angular orientation of the tool within the pipeline. A brush wheel assembly 30 is mounted upon the distal end of each support arm 28. Each support arm 28 is biased radially outwardly in order to ensure that its brush wheel assembly 30 is maintained in contact with the pipeline surface.

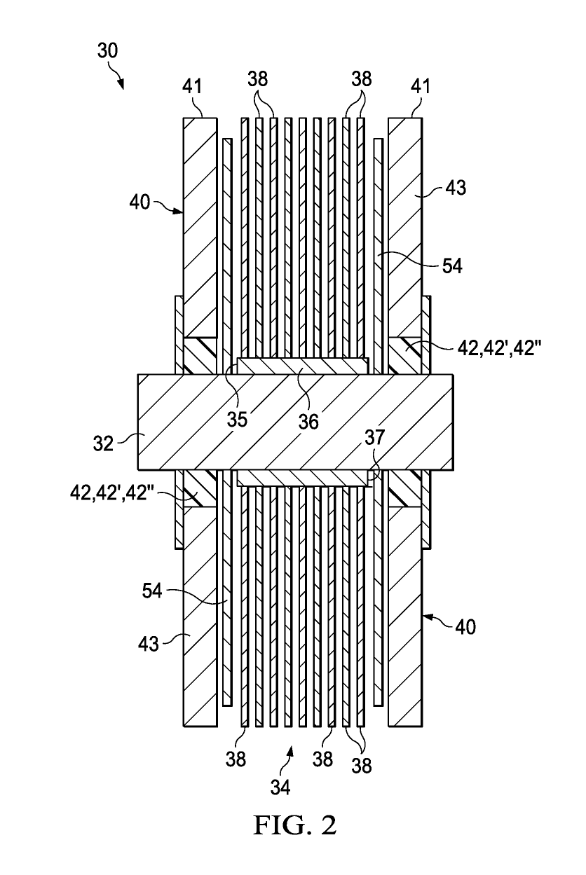

An exemplary brush wheel assembly 30 is illustrated in FIG. 2. The brush wheel assembly 30 includes an axle 32. The axle 32 is formed of electrically conductive material. The axle 32 passes through openings in the support arm 28 to secure brush wheel assembly components thereupon. A conductive brush wheel 34 is mounted upon the axle and includes a central, electrically-conductive hub 36 with electrically-conductive bristles 38 which extend radially outwardly therefrom. In certain embodiments, the bristles 38 are formed of steel. During operation, the bristles 38 maintain contact with the interior pipeline surface.

An active guide disc 40 is located adjacent each axial side 35, 37 of the brush wheel 34 or at least one axial side of the brush wheel 34. As is apparent from FIG. 2, the radius of each active guide disc 40 is approximately the same as the radius of the brush wheel 34 so that the outer radial edge 41 of each active guide disc 40 will be in contact with the pipeline surface at the same time that the bristles 38 of the brush wheel 34 are in contact with the pipeline surface. However, the radius of each active guide disc 40 can be different from the radius of the brush wheel 34, depending on design requirements. The active guide discs 40 each feature an outer contact disc 43 which is preferably formed of a rigid material. In a preferred embodiment, the contact discs 43 are formed of carbon steel.

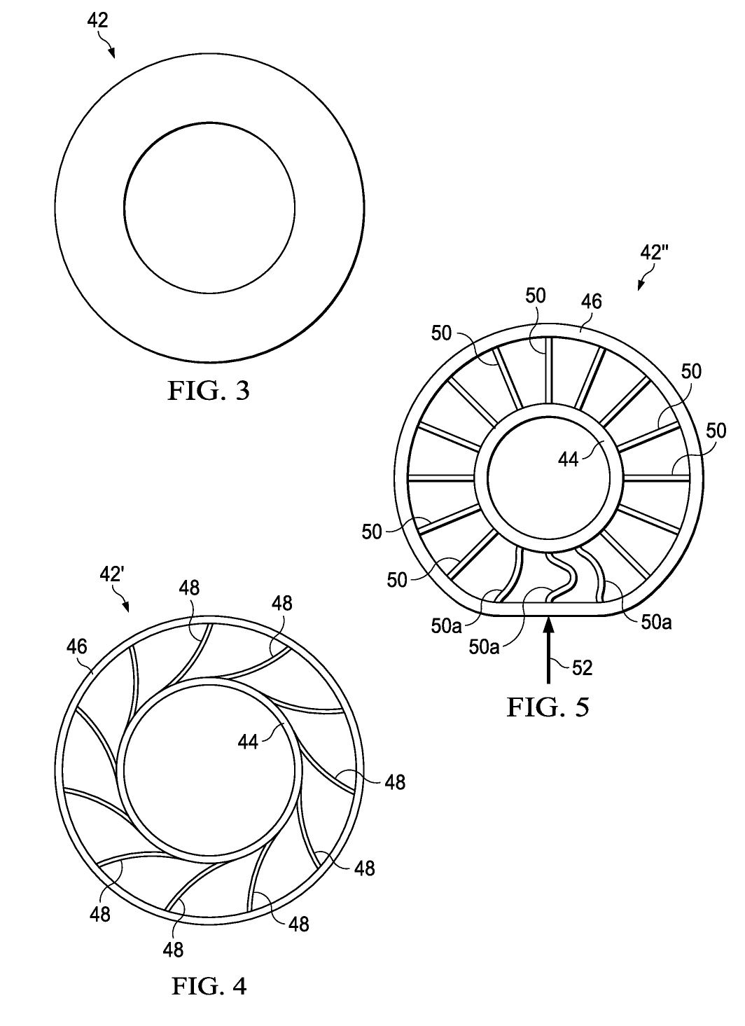

A circular axle dampener 42 is disposed radially between each contact disc 43 and the axle 32. Axle dampeners 42 isolate vibration of the contact discs 43 from the brush wheel and internal rotational contact. FIG. 3 illustrates an exemplary axle dampener 42 apart from other components of the brush wheel assembly 30. In the embodiment depicted in FIG. 3, the axle dampener 42 is unitarily formed of a flexible, deformable material which will permit absorption of vibration due to rolling of the brush wheel assembly 30, and in particular the contact disc 43, on the interior pipe surface. In a preferred embodiment, the axle dampeners 42 are formed of polyurethane.

FIG. 4 depicts an alternative axle dampener 42′. Axle dampener 42′ is made up of a circular inner frame 44 and a circular outer frame 46. A plurality of curved leaf springs 48 interconnect the inner and outer frames 44, 46. The leaf springs 48 will absorb vibration created by rolling of the brush wheel assembly 30 upon the pipeline surface. The leaf springs 48 will deform in response to forces imparted to the outer frame 46 by permitting relative motion between the inner and outer frames 44, 46. The leaf springs 48 therefore absorb vibrations of the active guide discs 40.

FIG. 5 depicts a further alternative axle dampener 42″. Axle dampener 42″ includes a circular inner frame 44 and a circular outer frame 46. A plurality of spokes 50 interconnect the inner and outer frames 44, 46. Preferably, each of the spokes 50 extends outwardly in a radial direction from the inner frame 44 to the outer frame 46. The spokes 50 are each fashioned of a semi-rigid material which will elastically deform (bend) in response to external force 52 upon the outer frame 46 and return to their original shape when the external force is removed. Elastic deformation of the spokes 50 will absorb vibration energy. Deformed spokes are illustrated at 50a in FIG. 5. The outer frame 46 may be elastically deformable as well.

Referring again to FIG. 2, an isolating film 54 is preferably disposed between each active guide disc 40 and the brush wheel 34. The isolating film 54 is preferably made of a plastic material and functions to encapsulate the bristles 38 of the brush wheel 54 and prevent the bristles 38 from spreading axially outwardly during use.

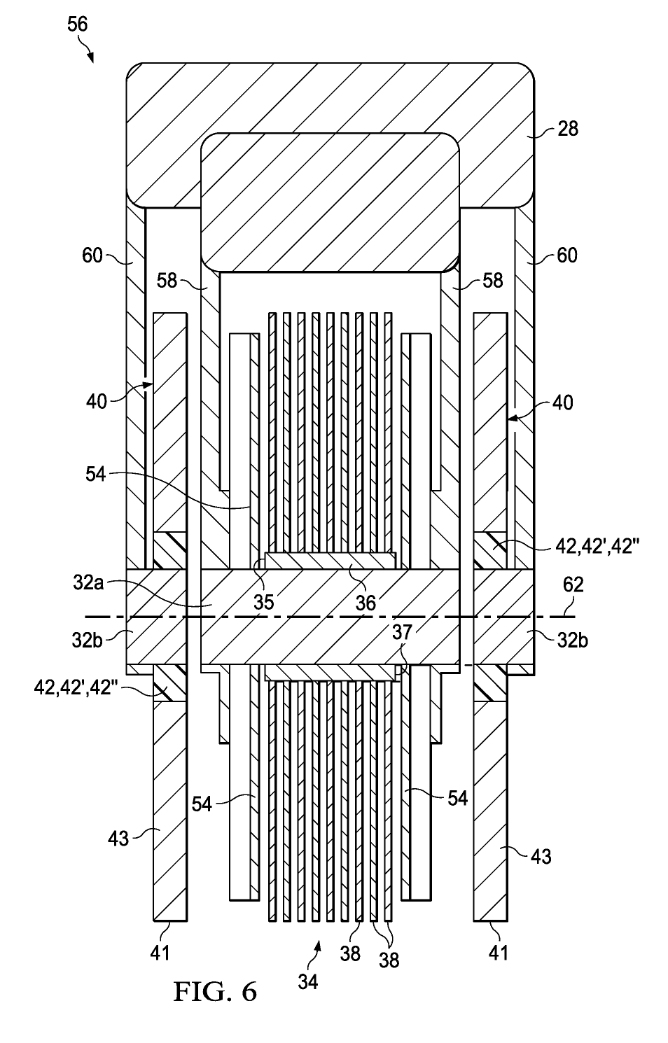

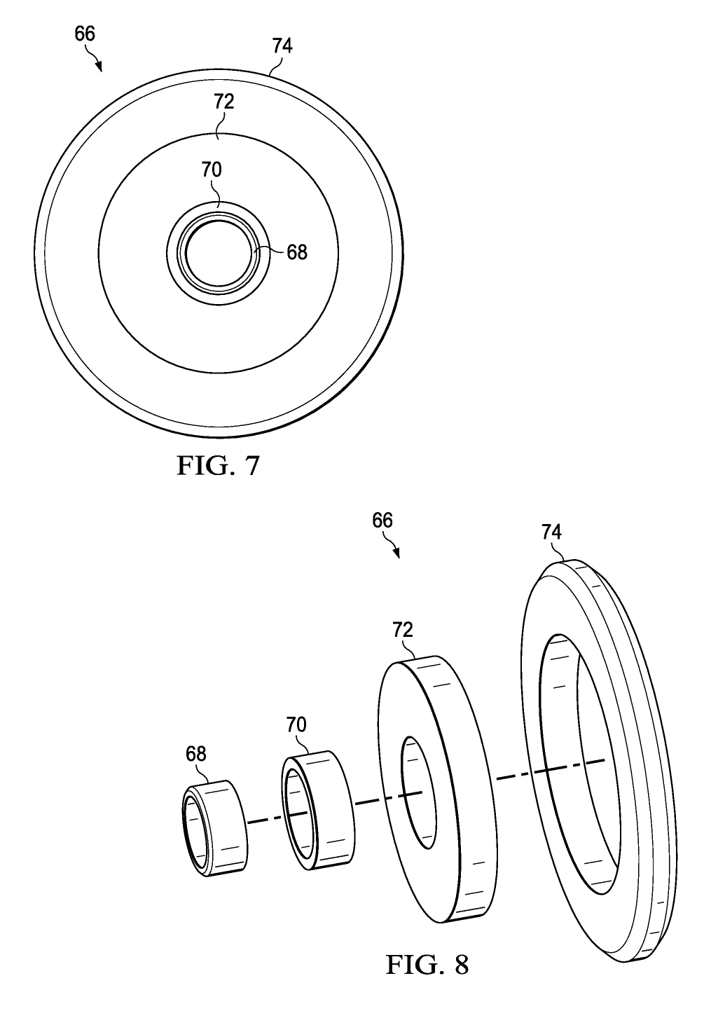

An alternative brush wheel assembly 56 is illustrated in FIG. 6 and incorporates an independent suspension, or separate axle, for carrying the brush wheel 34 and the active contact discs 40. The brush wheel assembly 56 is supported by support arm 28. Inner bracket 58 extends from the support arm 28 to an inner axle 32a. The inner axle 32a carries the brush wheel 34 and isolating film 54. Outer axles 32b are supported by an outer bracket 60. Outer axles 32b carry active guide discs 40 and associated axle dampeners 42, 42′ or 42″. The outer axles 32b are separate from the inner axle 32a but preferably share a common axis 62 so that the bristles 38 and the outer edges 41 of the active contact discs 40 are coextensive and will contact the surface of the pipeline at the same time. In particular embodiments, a drive wheel 64 is mounted upon the inner axle 32a. The drive wheel 64 may be driven by a chain drive (not shown) which would cause the drive wheel 64, inner axle 32a and brush wheel 34 to be rotated at a set speed.

FIGS. 7 and 8 illustrate a further construction for an exemplary active guide disc 66 which could be used with either of the brush wheels assemblies 30, 52 described previously. The active guide disc 66 would replace any or all of the active guide discs 40, 43 previously described. The active guide disc 66 includes a central glide bushing 68 and a rigid bushing 70 which radially surrounds the glide bushing 68. The glide bushing 68 is preferably formed of resilient plastic. The rigid bushing 70 may be made of steel, titanium or another suitable rigid material. A wheel guide dampener 72 radially surrounds the rigid bushing 70. In preferred embodiments, the rigid bushing 70 is bonded to the wheel guide dampener 72 so that the two members rotate as one. The rigid bushing 70 and wheel guide dampener 72 may be bonded together using a suitable acrylic adhesive or other adhesive. The wheel guide dampener 72 is preferably formed of polyurethane and functions as a resilient component to provide dampening.

A wheel guide 74 radially surrounds the wheel guide dampener 72. The wheel guide 74 is preferably formed of rigid material, such as carbon steel, and functions to engage the pipe surface. Preferably also, the wheel guide 74 is bonded to the wheel guide dampener 72 using an adhesive, such as a suitable acrylic adhesive.

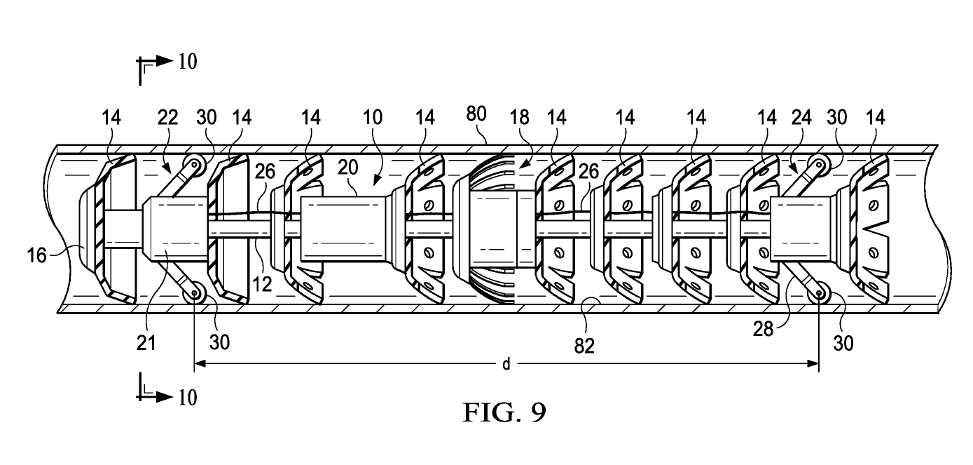

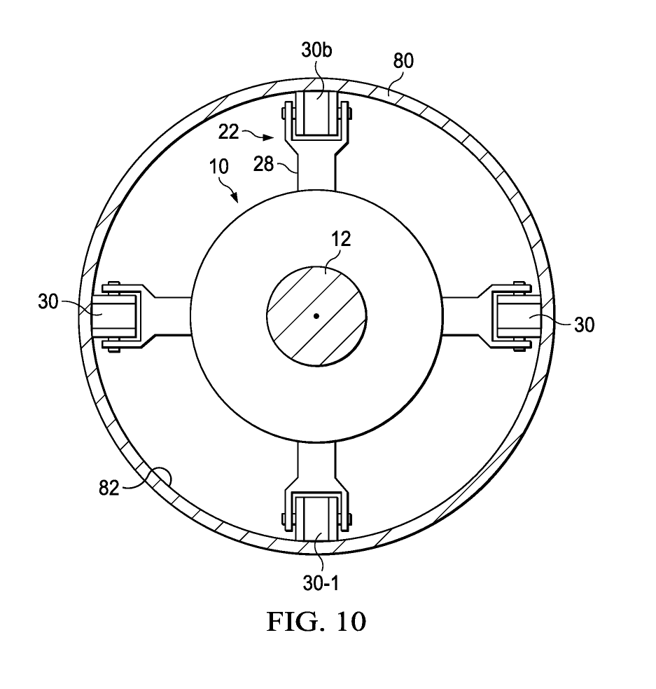

FIGS. 9 and 10 depict an exemplary tool 10 disposed within a surrounding pipe 80. The pipe 80 may be a portion of a longer pipeline. As can be seen in FIG. 9, each of the cups 14 contacts the interior surface 82 of the pipe 80. In addition, the brush wheel assemblies 30 are biased radially outwardly into contact with the interior surface 72. It should be understood that, while brush wheel assemblies 30 are illustrated in FIGS. 9-10, brush wheel assemblies 52 might be used as well in place of some or all of the wheel assemblies 30 shown. Distance “d” in FIG. 9 represents the length of pipe 80 over which a voltage differential is measured by the tool 10. As will be appreciated additionally with reference to FIG. 10, the lower brush wheel assembly 30-1 contacts the interior surface 82 within the lower half of the pipe 80 and, therefore, the lower brush wheel assembly 30-1 must bear the weight of the tool 10 during operation. For the lower brush wheel assembly 30-1, the rigid contact disc 43 portion of the active guide discs 40 will protect the bristles 38 of the brush wheels 34 from being deformed by the weight of the tool 10.

The brush wheel assemblies 30, 52 are normally preloaded, or biased radially outwardly to help ensure that positive contact is made between the bristles 38 and the interior surface 82. A certain load is applied to the brush wheel assemblies 30, 52 through support arms 28. In the instance depicted in FIGS. 9-10, it should be understood that gravity will tend to act upon the upper brush wheel assembly 30b to normally cause it to pull away from the interior surface 72. Preloading of the brush wheels assemblies 30, 52 will greatly assist in ensuring positive contact between the bristles 28 and the interior surface 82.

Where the brush wheel assembly 52 is used, separate and distinct amounts of preloading may be applied to the brush wheel 34 and the active guide discs 40. To do this, the inner bracket 58, which carries the brush wheel 34, has a different stiffness than the outer bracket 60 which carries the active guide discs 40. For example, if a preload force is applied through the support arm 28, the outer bracket 60 may have a lesser stiffness than the inner bracket 58, which permits it to absorb a portion of the preloading through bending. Thus, the active guide discs 40 would have a lower preload while the brush wheel 34 maintains a higher preload.

It should be understood that use of active guide discs 40 together with a brush wheel 34 will reduce any lateral stick-slip that might occur between the brush wheel bristles 38 and the pipe surface. In addition, the use of active guide discs 40 will reduce any slippage of the brush wheel 34 that might occur during rotation.

What is claimed is:

1. A device for monitoring conductivity of a pipe comprising:
a central shaft assembly to be inserted into the pipe;
first and second electrical contact assemblies which extend radially outwardly from the central shaft assembly to make electrical contact with the pipe;
a voltage measurement device operable to measure a voltage differential across a length of the pipe;
at least one of the first and second electrical contact assemblies includes a brush wheel assembly having:
a rotary brush wheel having bristles to contact the pipe to permit measurement of the voltage differential; and
an active guide disc which contacts the pipe when the bristles of the brush wheel contact the pipe to reduce dynamics and slippage of the brush wheel.

2. The device of claim 1 wherein the rotary brush wheel and the active guide disc are mounted upon a single axle.

3. The device of claim 1 wherein the rotary brush wheel is carried by a first axle and the active guide disc is carried by a second axle.

4. The device of claim 1 wherein the active guide disc comprises:
a radially outer rigid contact disc; and
an axle dampener to absorb vibrational energy between the contact disc and an axle.

5. The device of claim 4 wherein the axle dampener is formed of a flexible, deformable material.

6. The device of claim 4 wherein the axle dampener comprises:
an inner frame;
an outer frame; and
a plurality of leaf springs disposed radially between the inner and outer frames.

7. The device of claim 4 wherein the axle dampener comprises:
an inner frame;
an outer frame; and
a plurality of spokes disposed radially between the inner and outer frames, the spokes being elastically deformable to absorb vibratory energy.

8. The device of claim 1 further comprising an isolating film disposed between the brush wheel and the active guide disc.

9. The device of claim 3 wherein:
the first axle is supported by a first bracket;
the second axle is supported by a second bracket; and
the first and second brackets provide different degrees of stiffness, thereby applying different preloads to the first axle and the second axle.

10. A device for monitoring conductivity of a pipe comprising:
a central shaft assembly to be inserted into the pipe;
first and second electrical contact assemblies which extend radially outwardly from the central shaft assembly to make electrical contact with the pipe;
a voltage measurement device operable to measure a voltage differential across a length of the pipe;
at least one of the first and second electrical contact assemblies includes a brush wheel assembly having:
a rotary brush wheel having bristles to contact the pipe to permit measurement of the voltage differential, the rotary brush wheel presenting two axial sides; and
an active guide disc located adjacent each of the axial sides of the rotary brush wheel, each active guide disc presenting an outer radial edge which contacts the pipe when the bristles of the brush wheel contact the pipe to reduce slippage of the brush wheel.

11. The device of claim 10 wherein each active guide disc comprises:
a radially outer rigid contact disc; and
an axle dampener to absorb vibrational energy between the contact disc and an axle.

12. The device of claim 11 wherein the axle dampener is formed of a flexible, deformable material.

13. The device of claim 11 wherein the axle dampener comprises:
an inner frame;
an outer frame; and
a plurality of either leaf springs or spokes which are elastically deformable to absorb vibratory energy.

14. The device of claim 10 further comprising an isolating film disposed between the brush wheel and the active guide disc.

15. The device of claim 10 wherein the rotary brush wheel is carried by a first axle and the active guide disc is carried by a second axle.

16. The device of claim 15 wherein:
the first axle is supported by a first bracket;
the second axle is supported by a second bracket; and
the first and second brackets provide different degrees of stiffness, thereby applying different preloads to the first axle and the second axle.
